(19) United States
(12) Patent Application Publication
(10) Pub. No.: US 2004/0004220 A1
(43) Pub. Date: Jan. 8, 2004

(54) Thin film transistor

(76) Inventor: Koji Suzuki, Haguri-gun (JP)

Correspondence Address: Michael A. Cantor, Esq., CANTOR COLBURN LLP, 55 Griffin Road South, Bloom field, CT, 06002, US

(21) Appl. No.: 10/600,171

(22) Filed: Jun. 19, 2003

(30) Foreign Application Priority Data
Jun. 21, 2002 (JP) 2002-181491
Jun. 21, 2002 (JP) 2002-181492

(51) Int. Cl. H01L 29/76; H01L 31/036; H01L 31/112; H01L 21/00; H01L 21/84

(52) U.S. Cl. 257/66; 438/149

(57) ABSTRACT

In a thin film transistor having a semiconductor film provided above a substrate, a gate insulating film covering the semiconductor film, a gate electrode formed on the gate insulating film, and an interlayer insulating film covering the gate electrode, the gate electrode has a tapered shape wherein the width becomes wider from the side of the interlayer insulating film towards the gate insulating film. With this structure, the characteristics are stabilized. The electrode having a tapered shape can be formed through a first etching step wherein etching is applied to an electrode material layer to a degree where at least a portion of the electrode material layer remains and a second etching step wherein etching is applied to the electrode material layer while the mask is being ashed.

### BACKGROUND OF THE INVENTION

1. Field of the Invention

The present invention relates to a thin film transistor, and, in particular, to a shape for a gate electrode of a thin film transistor.

2. Description of the Related Art

Thin film transistors (hereinafter abbreviated to “TFT”) can be classified based on the position of a gate electrode into a “top gate type”, in which the gate electrode is provided above a semiconductor film, and a “bottom gate type”, in which the gate electrode is provided below the semiconductor film.

A structure of a top gate TFT in a related art will now be described referring to FIGS. 1A and 1B. FIG. 1A is a plan view of a TFT and FIG. 1B is a cross sectional diagram showing the cross section X-X in FIG. 1A. An insulating film 22 made of SiN (silicon nitride) and/or SiO₂ (silicon oxide) is layered on a transparent substrate 21 made of a material such as glass and a polycrystalline silicon film 23 is formed on the insulating film 22 in an island-like manner. Above the insulating film 22 and polycrystalline silicon film 23, a gate insulating film 24 made of SiN and/or SiO₂ is layered. Further, a gate electrode 25 made of Mo or the like is formed over the gate insulating film in a manner to intersect the polycrystalline silicon film 23. An interlayer insulating film 26 made of SiN and/or SiO₂ is layered on these structures to cover the gate electrode 25.

In the polycrystalline silicon film 23, a source region 23s and a drain region 23d are formed by doping impurity ions and a region between the source and drain regions 23s and 23d forms a channel region 23c. A source electrode 27 and a drain electrode 27 are respectively connected to the source region 23s and the drain region 23d through the gate insulating film 24 and the interlayer insulating film 26.

A TFT having a structure as described is suited for applications such as a display element, a light receiving element, etc. When the TFT is used in a display element, a plurality of TFTs is placed in a matrix form. In each TFT, a display electrode is connected to one of the source electrode and the drain electrode and a signal source or a power source is connected to the other one of the source electrode and the drain electrode.

When TFTs are employed for controlling and/or driving a display element in a display device having a liquid crystal display element or an organic electroluminescence element or the like as the display element for which further improvements in the yield factor and in the reliability are desired, in many cases, the display element is placed above the TFT. With such a structure, it can be presumed that improvements in the coverage of the insulating film covering the TFT will contribute to the improvements in the yield factor and in the reliability.

In a top gate TFT as described above, an interlayer insulating film 26 is formed above the gate electrode 25. In such a structure, it can be presumed that improvements in the step coverage of the interlayer insulating film 26 are advantageous. As a specific method for realizing this improvement in step coverage, a method can be considered wherein the gate electrode 25 is formed to have side surfaces with a tapered surface, that is, the gate electrode 25 is formed such that its width 25 becomes narrower from the side of the gate insulating film 24 toward the interlayer insulating film 26. In a method for forming the tapered shape, when a metal material such as Mo, MoW, W, etc. is used as in an electrode material layer, a resist mask is formed and an etching process is applied using a mixture of SF₆ (sulfur fluoride) which is a fluorine-based gas and O₂ (oxygen) (this mixture is hereinafter referred to as “SF₆/O₂”).

In this method, however, when an etching process is applied using SF₆/O₂, a portion of the gate insulating film is also etched because a selection ratio which is a ratio between an etching rate of the gate electrode 25 with respect to SF₆/O₂ and an etching rate of the gate insulating film 24 formed below the gate electrode 25 and made of SiN and/or SiO₂ is very small. Thus, the gate insulating film is also etched in addition to the electrode material layer, the amounts of remaining gate insulating film varies, and, when impurity ions are doped into the semiconductor film through the gate insulating film 24 with the gate electrode 25 used as a mask, the amount of impurity ions introduced into the polycrystalline silicon film becomes non-uniform among TFTs. As a result, TFT characteristics may be unstable. In addition, because the polycrystalline silicon film has a smaller thickness than the gate insulating film above the polycrystalline silicon film, it can be expected that varying the energy for doping the impurity ions into the semiconductor film based on the remaining amount of gate insulating film to obtain a constant amount of doped impurity ions is very difficult.

In addition, when a taper angle, which is an angle between the plane on which the gate electrode 25 is formed and the tapered side surface of the gate electrode 25, is set at a value smaller than necessary, the end portions of the gate electrode 25 become thin, resulting in reduction in the uniformity of conversion difference which is a difference between a width of a resist applied and patterned as a mask prior to the etching process and a width of the obtained gate electrode 25, which in turn may cause variations in the width of the gate electrode 25 and variation in the characteristics among the TFTs. This may also become a factor causing instability in the characteristics among TFTs. On the other hand, when the taper angle of the gate electrode 25 is large, step coverage of the interlayer insulting film 26 formed above the gate electrode 25 becomes inferior, and, consequently, advantages that may be obtained through the use of the tapered shape cannot be obtained. Thus, it is desired not merely to form a gate electrode having a tapered shape, but rather to form a gate electrode with an optimized tapered shape.

### SUMMARY OF THE INVENTION

The present invention advantageously provides a thin film transistor having stable characteristics.

According to one aspect of the present invention, there is provided a method for manufacturing a thin film transistor, comprising the steps of forming a semiconductor film above a substrate; forming a gate insulating film to cover the semiconductor film; forming a gate electrode on the gate insulating film; forming a source region and a drain region in the semiconductor film; and forming an interlayer insulating film on the gate electrode, wherein in the formation of the gate electrode, an electrode material layer is layered on the gate insulating film; a mask pattern is formed on the electrode material layer; a first etching process is applied in which the electrode material layer is etched using gas containing fluorine or a mixture containing fluorine and oxygen and with the mask pattern as a mask to a degree wherein a portion of the electrode material layer remains; and a second etching process is applied in which the electrode material layer is etched using a gas containing a mixture of chlorine and oxygen.

According to another aspect of the present invention, there is provided a method for manufacturing a thin film transistor, comprising the steps of forming a semiconductor film above a substrate; forming a gate insulating film to cover the semiconductor film; forming a gate electrode on the gate insulating film; forming a source region and a drain region within the semiconductor film; and forming an interlayer insulating film on the gate electrode, wherein in the formation of the gate electrode, an electrode material layer is layered on the gate insulating film; a mask pattern is formed on the electrode material layer; and a first etching process and a second etching process are applied to the electrode material layer with the mask pattern made of a resist material as a mask, wherein, in the first etching process, an etching gas having a smaller etching selection ratio between the electrode material layer and the gate insulating film than an etching gas used in the second etching process and having a faster etching rate of the electrode material layer than the etching gas of the second etching process is used, and the electrode material layer is etched to a degree so that a predetermined thickness of the electrode material layer remains in regions not covered by the mask, and, in the second etching process, an etching gas having a larger etching selection ratio between the electrode material layer and the gate insulating film than the etching gas used in the first etching process and having a larger ashing rate of the mask pattern than the etching gas used in the first etching process is used to etch the electrode material layer remaining in the predetermined thickness, so that a gate electrode having a tapered shape wherein the side surface is inclined such that the width becomes narrower toward the upper surface is obtained.

According to another aspect of the present invention, there is provided a method for forming a thin film transistor having a semiconductor film and a gate electrode formed above a substrate, the method comprising a film forming step for layering an electrode material layer above the substrate; a first etching step for etching, in a reaction chamber of an inductively coupled plasma apparatus having an inductively coupled plasma source and a biasing source, at least a portion of the electrode material layer using a mask pattern formed on the electrode material layer as a mask and by activating only the inductively coupled plasma source; and a second etching step for etching, in a reaction chamber of the inductively coupled plasma apparatus, the electrode material layer which is etched in the first etching step by activating both the inductively coupled plasma source and the biasing source, wherein a gate electrode having a side surface with a tapered shape is formed.

According to yet anther aspect of the present invention, it is preferable that, in the method for manufacturing a thin film transistor, in the first etching step, a gas containing fluorine or a mixture of fluorine and oxygen is used as the etching gas; and in the second etching step, a gas containing chlorine and oxygen is used as the etching gas.

According to another aspect of the present invention, it is preferable that, in the methods for manufacturing a thin film transistor, the source region and the drain region are formed by doping impurities into the semiconductor film through the gate insulating film.

According to another aspect of the present invention, it is preferable that, in the methods for manufacturing a thin film transistor, the gate insulating film be obtained by layering a SiN film and a SiO₂ film or by forming one of the SiN film and SiO₂ film.

According to still another aspect of the present invention, it is preferable that, in the methods for manufacturing a thin film transistor, for the gas in the first etching process, a fluorine-based gas and an oxygen-based gas are mixed in an approximately equal volume ratio.

By forming a gate electrode through a method as described, superior step coverage can be achieved in layers formed above the gate electrode, in particular, in an insulating film covering the gate electrode, enabling improvement in the reliability and stability of devices which use such thin film transistors. In addition, because it is possible to uniformly and stably form a tapered shape in the gate electrode, it is possible to provide thin film transistors having stable characteristics.

Moreover, because etching of a gate insulating film during formation of the gate electrode having a tapered shape can be prevented, variation in thickness of the gate insulating films tends not to occur, resulting in an advantage that thin film transistors can be provided having semiconductor films which are uniformly doped with ions in the impurity ion doping step.

In addition, it is possible to etch the gate electrode while preventing pollution of the reaction chamber, enabling simplification of the steps such as cleaning of the reaction chamber, and, consequently, improvement in the reliability of the device while reducing the manufacturing cost.

According to another aspect of the present invention, there is provided an active matrix display device in which a pixel section and a peripheral driver circuit provided in the periphery of the pixel section for driving the pixel section are formed on a substrate, wherein each pixel in the pixel section comprises a display element and a pixel thin film transistor for controlling the display element; the peripheral circuit comprises a plurality of driver thin film transistors; the pixel thin film transistor and the driver thin film transistors each comprises a semiconductor film made of the same material among the thin film transistors; a gate insulating film formed to cover the semiconductor film; and a gate electrode formed on the gate insulating film, and the gate electrode of each of the transistors has a tapered shape wherein the side surface is inclined such that the width becomes narrower towards the upper layer and away from the gate insulating film.

According to another aspect of the present invention, it is preferable that, in the active matrix display device, the gate insulating film may comprise one or both of SiN and SiO₂.

According to another aspect of the present invention, it is preferable that, in the active matrix display device, the pixel thin film transistor is covered by an interlayer insulating film, and the display element is formed above the interlayer insulating film.

As described, similar to a top gate TFT, in a configuration wherein a thin film transistor is formed below the display element, with a gate electrode having a tapered shape provided in an upper layer in the transistor, it is possible to improve the coverage of the interlayer insulating film or the like which covers the gate electrode and flatness of the film in its upper surface, and thereby improve the reliability of the display element.

According to another aspect of the present invention, it is preferable that, in the active matrix display element, each of the pixels further comprises a storage capacitor; the storage capacitor has a structure wherein a first electrode made of the same material as the gate electrode and a second electrode which is constructed by the semiconductor film are disposed with the gate insulating film therebetween; and the first electrode formed on the gate insulating film has a tapered shape wherein the side surface is inclined such that the width becomes narrower towards the upper layer and away from the gate insulating film.

According to another aspect of the present invention, it is preferable that, in the active matrix display element, taper angles between a formation plane and the side surface of the gate electrode of the pixel thin film transistor and of the driver thin film transistor is equal to the taper angle between the formation plane and the side surface of the first electrode of the storage capacitor.

As described, with regard to thin film transistors formed on a same substrate and a storage capacitor formed using the same layers as the thin film transistors, by forming the gate electrodes and the first electrode into a tapered shape, it is possible to simultaneously and effectively form these electrode layers in the same step, and, by applying a two-step etching process as described above, the electrodes can be precisely formed. Therefore, a top gate thin film transistor having a tapered shape can be employed in display devices wherein the resolution grows increasingly higher.

### BRIEF DESCRIPTION OF THE DRAWINGS

FIG. 1A is a plan view showing a structure of a thin film transistor according to a related art.

FIG. 1B is a cross sectional diagram showing a structure of a thin film transistor according to a related art.

FIG. 2 is a cross sectional diagram showing a thin film transistor according to a preferred embodiment of the present invention.

FIGS. 3A, 3B, 3C, 3D, and 3E are diagrams showing manufacturing steps of a top gate type thin film transistor according to a preferred embodiment of the present invention.

FIG. 4 is a schematic diagram showing an inductively coupled plasma apparatus according to a preferred embodiment of the present invention.

FIGS. 5A, 5B, 5C, and 5D are diagrams showing manufacturing steps of a bottom gate type thin film transistor according to a preferred embodiment of the present invention.

FIG. 6A is a diagram schematically showing a circuit structure of an active matrix display device according to a preferred embodiment of the present invention.

FIG. 6B is a schematic diagram showing a planar structure of a pixel in an active matrix display device of FIG. 6A.

FIG. 6C is a diagram schematically showing a cross sectional structure of TFTs used in a pixel section and in a peripheral driver circuit.

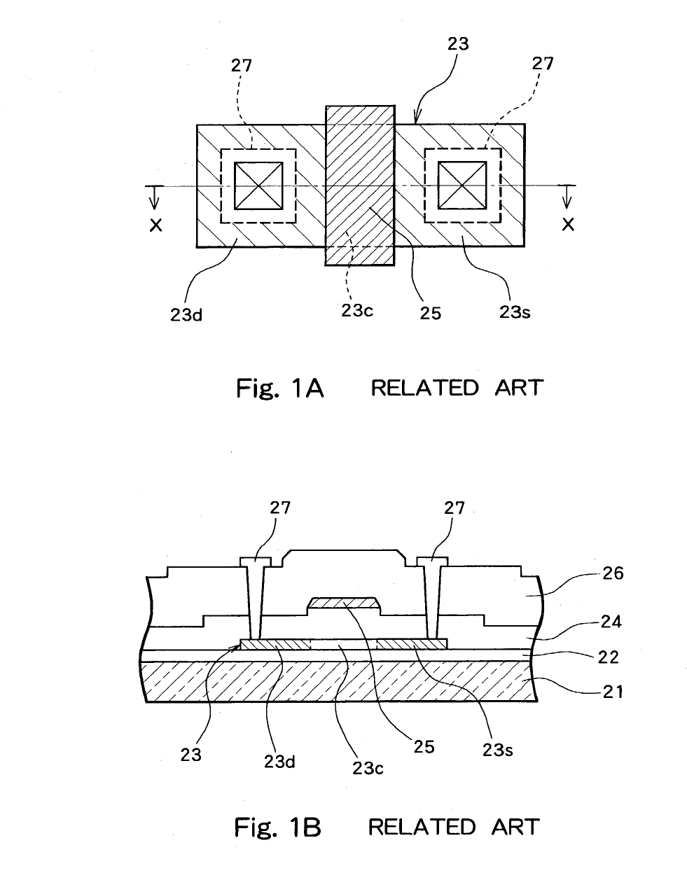

### DESCRIPTION OF PREFERRED EMBODIMENT

A preferred embodiment of the present invention (hereinafter referred to simply as “the embodiment”) will now be described with reference to the drawings.

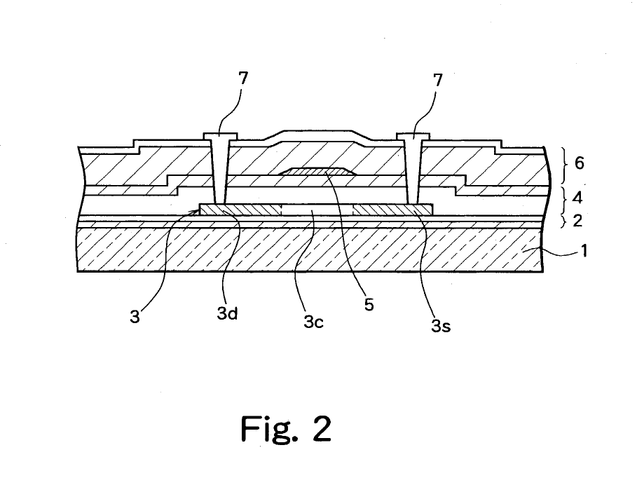

FIG. 2 shows a cross sectional structure of a TFT according to the embodiment of the present invention. The structure of the TFT according to the embodiment will now be described referring to FIG. 2.

An insulating film (buffer film) 2 wherein SiN and SiO₂ are layered in that order is formed on a transparent substrate 1 made of glass or the like and a polycrystalline silicon film 3 is formed on the insulating film 2. The polycrystalline silicon film 3 can be formed by various methods such as, for example, a method for directly forming a polycrystalline silicon film through CVD or by a method for forming an amorphous silicon film and then crystallizing the amorphous silicon film to obtain the polycrystalline silicon film. In the latter method, a low temperature process can be employed which allows for the use of a low melting point glass as the transparent substrate 1.

Above the insulating film 2 and the polycrystalline silicon film 3, SiO₂ and SiN are layered, in that order, as a gate insulating film 4. A gate electrode 5 made of Mo or the like is formed and patterned on the gate insulating film 4 to partially overlap the polycrystalline silicon film 3. Above these layers, SiN and SiO₂ are layered in that order as an interlayer insulating film 6 which covers the gate electrode 5.

Impurity ions are doped into the polycrystalline silicon film 3 through the gate insulating film with the gate electrode 5 used as a mask so that a region of the polycrystalline silicon film 3 below the gate electrode 5 becomes a channel region 3c and regions on both sides of the channel regions 3c are doped with impurity ions which move through the gate insulating film and form a source region 3s and a drain region 3d. A source electrode and a drain electrode 7 are electrically connected to the source region 3s and drain region 3d, respectively, through contact holes formed through the gate insulating film 4 and the interlayer insulating film 6.

According to the embodiment, the gate electrode 5 is formed through a two-step etching process and has a tapered cross sectional shape wherein the side surface is tapered such that the side surface becomes wider at the side of the gate insulating film.

A method for forming a gate electrode 5 having such a structure will now be described. First, a resist corresponding to a desired pattern of a gate electrode is formed on a layer 35 of an electrode material layered on the gate insulating film 4. Then, using the resist as a mask, a first etching process is applied using gas such as, for example, SF₆/O₂, to a degree wherein the electrode material layer 35 is not completely eliminated and a predetermined thickness of the electrode material layer 35 remains. Then, another etching process is applied while ashing the resist and using a mixture of Cl₂ (chlorine) and O₂ (this gas mixture will hereinafter be referred to as “Cl₂/O₂ gas”), which has a high selection ratio between the electrode material layer 35 and the gate insulating film. In this manner, a gate electrode 5 having a tapered shape is formed. Here, in the first etching process, etching is applied to a degree such that a portion of the total thickness of the electrode material layer 35 to be etched remains and in the second etching process, the electrode material layer which remains in a region to be etched with a thin thickness is selectively etched. As a result, the gate insulating film 4 below the electrode material layer 35 is not etched or etched only to a small degree. This results in less variation in the thickness of the gate insulating film among a plurality of TFTs formed on the substrate. Thus, it is possible to inhibit variation in the amount of ions doped into the polycrystalline silicon film 3 when the impurity ions are doped through the gate insulating film as described above and provide TFTs having stable operational characteristics.

Accordingly, a TFT of the embodiment is suited for controlling or driving a display element or a light receiving element.

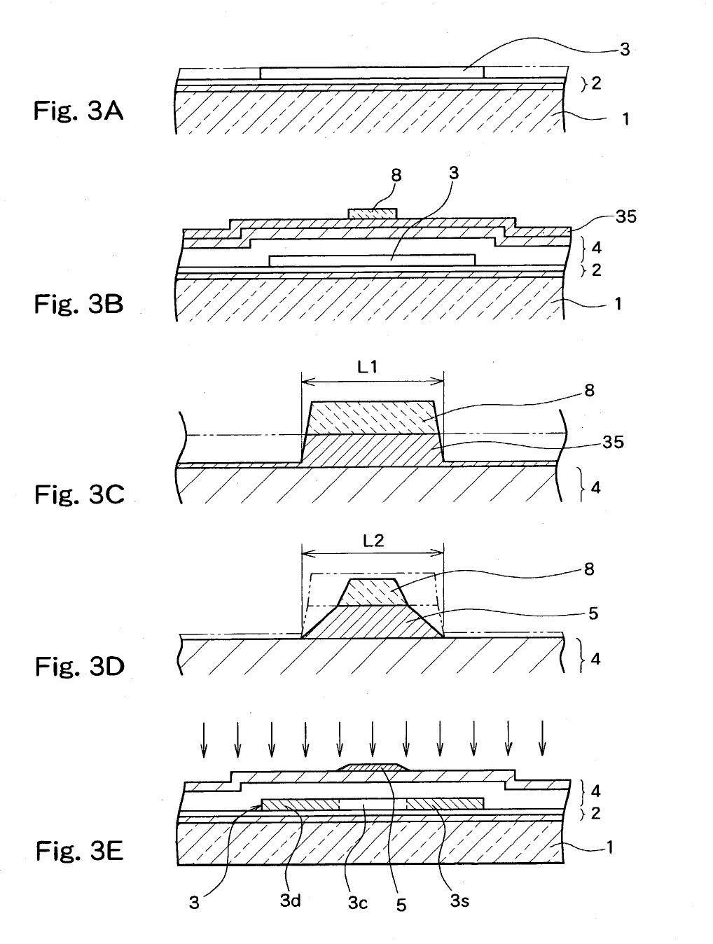

FIGS. 3A-3E are cross sectional views showing a TFT in different manufacturing stages showing an embodiment of a method for forming a TFT according to the present invention. A structure of a TFT of the embodiment will now be described referring to FIGS. 3A-3E.

FIG. 3A is a cross sectional diagram showing a first stage. In this stage, an insulating film 2 is first formed by layering SiN and SiO₂ in that order on a transparent substrate 1, and then a polycrystalline silicon film 3 is formed. As a method for forming the polycrystalline silicon film 3, various methods can be employed including, for example, a method for layering an amorphous silicon layer on the insulating film 2, crystallizing the amorphous silicon by anneal treatment to obtain a polycrystalline silicon film, and patterning the polycrystalline silicon film, and a method wherein an amorphous silicon film is layered on the insulating film 2, patterned, and annealed to form a polycrystalline silicon film.

FIG. 3B is a cross sectional diagram showing a second stage. In this stage, an insulating film 4 made of SiO₂ and SiN is layered over the insulating film 2 and the polycrystalline silicon film 3. Then, an electrode material layer 35 made of Mo is layered and a resist 8 for use in forming a gate electrode is formed on the electrode material layer 35.

FIG. 3C is a cross sectional diagram showing a third stage. In FIG. 3C, the portion of the gate insulating film 4, electrode material layer 35, and resist 8 is enlarged. This stage is the first etching stage of the gate electrode and a plasma etching process is applied to the electrode material layer using SF₆/O₂. Because SF₆/O₂ has a low selection ratio between the electrode material layer and the gate insulating film below the electrode material layer (the selection ratio is approximately 5), the etching process in this stage is terminated before the electrode material layer 35 is completely etched, that is, before the gate insulating film 4 below the electrode material layer 35 is exposed. With such a configuration, etching of the gate insulating film 4 is prevented.

Although it is also possible to perform the etching process using only SF₆, because addition of O₂ increases the etching rate, it is preferable to use SF₆/O₂ to achieve faster etching. In addition to a characteristic to hasten the etching rate, O₂ also has a characteristic to ash the resist. If the resist 8 is ashed in the first etching stage, it becomes difficult to control the taper. Thus, in order to increase the etching rate while preventing too much ashing of the resist 8, it is preferable to use a mixture of SF₆/O₂, wherein the mixture ratio is approximately 1:1.

FIG. 3D is a cross sectional diagram showing a fourth stage. The portion enlarged in FIG. 3C is enlarged also in FIG. 3D. This stage is a second etching stage of the gate electrode. First, a plasma etching process using Cl₂/O₂ is applied to the electrode material layer 35 still remaining after the third stage. Because the selection ratio of Cl₂/O₂ between electrode material layer and the gate insulating film is 30 or greater, it is possible to selectively etch the electrode material layer. In addition, as described, the resist is ashed by O₂, which allows for formation of a tapered shape in the gate electrode to be formed. Regarding the tapered shape, a desired angle can be obtained by controlling the mixture ratio of Cl₂/O₂ and/or the power of the plasma source of the etching device. In this stage, it is preferable to use a configuration wherein the mixture ratio of Cl₂ and O₂ is approximately 1:1 and an angle of taper is 15 degrees to 60 degrees.

FIG. 3E is a cross sectional diagram showing a fifth stage. In this stage, impurity ions corresponding to the type of the transistor to be formed, either P type or N type, are doped through a self-alignment method using the gate electrode 5 as a mask. When a p-ch type transistor is to be formed, a p-type ion such as B (boron) is doped and when an n-type transistor is to be formed, an n-type ion such as P (phosphorus) is doped. As a result of this doping, a channel region 3c is formed in a region of the polycrystalline silicon film 3 covered by the gate electrode 5, and a drain region 3d and a source region 3s are formed on both sides of the channel region 3c. Because it is possible to precisely control the amount of the gate insulating film remaining through the two-step etching process as described, impurity ions can be uniformly doped and TFTs having stable operational characteristics can be obtained.

After the doping of the impurity ions, an interlayer insulating film 6 is layered over the gate insulating film 4 and the gate electrode 5. Then, contact holes are formed through the interlayer insulating film 6 and the gate insulating film 4 in regions of the gate and interlayer insulating films 4 and 6 corresponding to the source region 3s and the drain region 3d and the contact hole is filled with a metal or the like to form a source electrode 7 and a drain electrode 7 respectively connected to the source region 3s and the drain region 3d. With the described method, a top gate TFT having a structure as shown in FIG. 2 can be obtained.

When the etching process is applied using Cl₂/O₂, MoCl₆ formed as a result of the etching is inferior in volatility, and thus a problem occurs in that the reaction chamber is polluted by MoCl₆ adhering to the reaction chamber. However, because most of the electrode material layer is etched in the first etching stage of the gate electrode using SF₆/O₂, the amount of etching using Cl₂/O₂ can be maintained at a small amount, and thus the degree of pollution can be maintained at a low level.

On the other hand, MoF₆ generated in the etching process using SF₆/O₂ is highly volatile, and thus the reaction chamber is not polluted. Although, as described above, a small amount of MoCl₆ produced in the second etching process is inferior in terms of volatility, it is possible to vaporize MoCl₆ along with MoF₆ through an action of MoF₆ created in the first etching stage applied to a new TFT substrate introduced for subsequent etching. As such, by repeating the first etching stage and the second etching stage for the gate electrodes in the same reaction chamber, it is possible to automatically clean the polluted reaction chamber. This advantage becomes more significant by reducing the thickness to be processed in the second etching stage, that is, by removing as much gate electrode material as possible in the first etching stage.

Next, a configuration wherein an inductively coupled plasma (hereinafter abbreviated to “ICP”) apparatus is used in the first and second etching stages in the manufacturing stages will be briefly described.

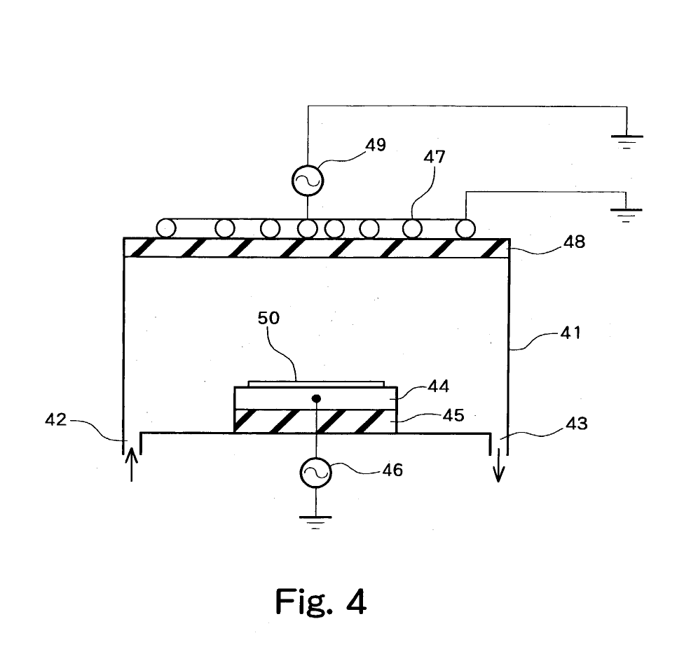

FIG. 4 schematically shows a structure of an ICP apparatus, and the ICP apparatus will be described referring to FIG. 4. A reaction chamber 41 where the plasma treatment takes place contains a conductive material and is fixed to a ground potential. The reaction chamber 41 is provided with a gas entrance 42 for introducing etching gas and an exit 43 for discharging the gas and any residuals of the etching process. A lower electrode 44 is insulated from the reaction chamber 41 with an insulating body 45 therebetween and is electrically connected to a first high frequency power source 46 which is a biasing source. An inductively coupled coil 47 having a helical shape is provided above the reaction chamber 41 with an insulating body 48 formed therebetween, and has a terminal on the central side electrically connected to a second high frequency power source 49 which is an inductively coupled plasma source and the other terminal connected to the ground. A sample 50 such as TFT to which processes before the etching process are applied is placed on the lower electrode 44.

In the first etching stage shown in FIG. 3C, only the high frequency power source 49 which is the inductively coupled plasma source of the ICP apparatus is switched on and the electrode material layer 35 is etched using SF₆/O₂. Here, the etching process is terminated before the electrode material layer 35 is completely etched, that is, before the gate insulating film 4 below the electrode material layer 35 is exposed by etching.

Then, in the second etching stage shown in FIG. 3D, while flowing Cl₂/O₂ through the ICP apparatus, the high frequency power source 46 which is the biasing source is switched on in addition to the high frequency power source 49 whish is the inductively coupled plasma source to etch the electrode material layer 35 remaining from the previous stage. Because the selection ratio of Cl₂/O₂ between the electrode material layer and the gate insulating film is 30 or greater, it is possible to selectively etch only the electrode material layer. In addition, as the power of the biasing source is increased, the etching of the electrode material layer and the ashing of the resist caused by O₂ are both accelerated, enabling formation of a tapered shape in the gate electrode. This tapered shape can be formed with a desired angle by varying the mixture ratio of Cl₂ and O₂ and/or the power of the biasing source. For example, under the conditions of the mixture ration (flow rate of Cl₂/O₂ of 200/200 Sccm (standard cubic centimeter per minute) and the power of the biasing source of 300 W, a taper angle of 20° can be formed. Thus, the precision of a conversion difference which is a difference between a width (L1) of the applied resist before the etching and a width (L2) of the gate electrode on the side of the gate insulating film after the etching can be improved. In this stage, it is preferable to set the mixture ratio of Cl₂ and O₂ to 1:1 and to form a taper having an angle of 15 degrees to 60 degrees.

Because the amount of the gate insulating film remaining can be precisely controlled using the two-step etching process as described, it is possible to uniformly dope impurity ions and to obtain a TFT having a structure as shown in FIG. 2 and having stable operational characteristics through the fifth stage subsequent to the etching process.

Next, a configuration wherein a bottom gate TFT is created using the IPC apparatus will be described.

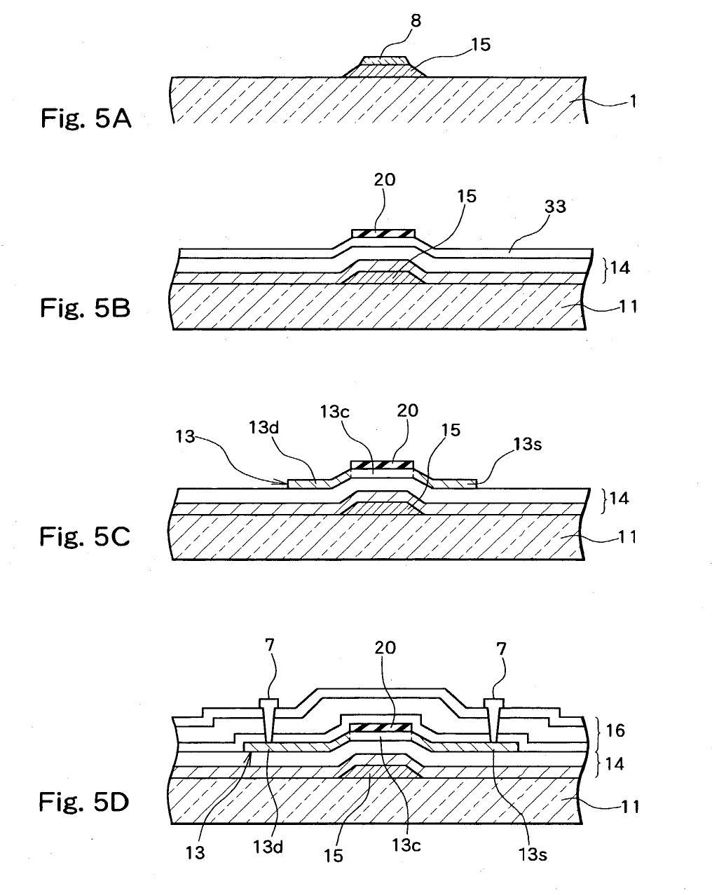

FIGS. 5A-5D show manufacturing stages of a bottom gate TFT. A method for manufacturing a TFT according to the embodiment will now be described referring to FIGS. 5A-5E.

FIG. 5A is a cross sectional diagram showing a first stage. In this stage, a gate electrode 15 having a tapered shape is formed on a transparent substrate 11 made of glass or the like. Similar to a method for forming the gate electrode 5 described above, with a first and second etching stages applied in order, the side surface of the gate electrode 15 can be formed in a tapered shape with high precision. In the example shown in FIG. 5A, because the substrate provided below the gate electrode 15 is made of glass, the gate electrode 15 can be more selectively etched compared to a top gate TFT having a SiO₂ or SiN layer below the gate electrode. When an insulating film (buffer layer) 2 having a two-layered structure of SiN/SiO₂ is formed on the surface of the glass substrate 11 in order to prevent mixture of impurities from the glass substrate 11 as in the structure shown in FIG. 3A, the side surface of the gate electrode 15 can be precisely formed into a tapered shape through the first and second etching stages.

FIG. 5B is a cross sectional diagram showing a second stage. In this stage, a gate insulating film 14 made of SiN and SiO₂ is layered on the gate electrode 15. On the gate insulating film 14, a polycrystalline silicon material film 33 is formed by annealing amorphous silicon and a stopper 20 is formed in a region where the gate electrode and the polycrystalline silicon material layer 33 overlap.

FIG. 5C is a cross sectional diagram showing a third stage wherein p type or n type ions corresponding to the type of transistor to be formed are doped into the polycrystalline silicon material film 33 using the stopper 20 as an impurity doping mask. With this doping, a channel region 13c is formed in a region of the polycrystalline silicon material layer 33 covered by the stopper 20 and a drain region 13d and a source region 13s are formed in the regions on both sides of the channel region 13c. The polycrystalline silicon material film 33 is patterned leaving the portion overlapping the gate electrode and a predetermined width on both sides of this portion, to form a polycrystalline silicon layer 13 which functions as the active layer of the TFT.

FIG. 5D is a cross sectional diagram showing a fourth stage. In this stage, SiO₂, SiN, and SiO₂ are layered, in that order, to cover the patterned polycrystalline silicon layer 13 to form an interlayer insulating film 16. Then, contact holes are formed in regions of the interlayer insulating film 16 and gate insulating film 14 corresponding to the source region 13s and the drain region 13d, through the interlayer insulating film 16 and the gate insulating film 14. A metal or the like is filled into the contact holes to form a source electrode 17 and a drain electrode 17 connected respectively to the source region 13s and the drain region 13d.

Through a method as described, a gate electrode having a tapered shape is formed and a bottom gate TFT having a structure as shown in FIG. 5D is created.

The present invention is not limited to the described embodiment and various modifications can be made. For example, with regard to the materials, the structures, or the like forming the TFT, instead of a glass substrate, a quartz glass may be used as the transparent substrate, or, alternatively, a non-transparent substrate maybe used. With regard to the material of the insulating film, gate insulating film, and interlayer insulating film over the substrate, each of which is made of SiN and SiO₂, it is also possible, for example, to use only one of SiN and SiO₂, or other insulating film material may be used. In addition, the layering order may be different. It is preferable, however, that SiO₂ is in contact with the semiconductor film (polycrystalline silicon film). As the electrode material layer, in addition to Mo, other high melting point metal such as, for example, MoW and W may be used. Furthermore, the method for forming each layer of the TFT may be plasma CVD.

The gas to be used in etching for forming the gate electrode may be another fluorine-based gas in which a Mo containing compound produced as a result of the etching is highly volatile such as, for example, CF₄ in place of SF₆ used in the embodiment. It is also possible to use a chlorine-based gas having a high selection ratio between the gate electrode material layer and the gate insulating film such as, for example, HCl or the like in place of Cl₂. The steps in a two-step etching process may be performed in different chambers.

In the ion doping stage for the top gate TFT, a method other than the self-alignment method may be used. In the manufacturing method for the bottom gate TFT, a stage for removing the stopper may be additionally included. In the stage for forming the polycrystalline silicon film, the order of patterning and ion doping of the polycrystalline silicon material film may be reversed.

According to the embodiment, by employing a two-step etching process wherein SF₆/O₂ having a low selection ratio is used to etch a large portion of the electrode material layer and, then, Cl₂/O₂ having a high selection ratio is used for etching of the remaining electrode material layer, it is possible to selectively etch the electrode material layer and form a gate electrode having a desired tapered shape, resulting in advantages such as, for example, inhibition of variation in the thickness of the gate insulating film, which consequently enables uniform ion doping in the subsequent impurity ion doping stage into the polycrystalline silicon layer which will function as the active layer. Thus, thin film transistors having superior step coverage and stable operational characteristics can be provided. In addition, even when the reaction chamber is polluted in the etching process using Cl₂/O₂, the reaction chamber can be automatically cleaned in the subsequent etching process using SF₆/O₂.

In addition, according to the embodiment, by employing a two-step etching process wherein only an inductively coupled plasma source is activated in a first etching stage for partially etching the electrode material layer and both the inductively coupled plasma source and a biasing source are activated in the second etching stage to etch the remaining portion of the electrode material layer while ashing the resist, it is possible to very precisely form a gate electrode having a desired taper angle. Thus, the method also has advantages such as improvements in the precision of conversion difference and provision of TFTs having more stable characteristics.

Moreover, by using a gas containing fluorine or a gas containing a mixture of fluorine and oxygen as the etching gas in the first etching stage and a gas containing chlorine and oxygen as the etching gas in the second etching stage, the taper angle can be controlled with a high precision, and, at the same time, pollution in the reaction chamber can be prevented. In addition, because it is possible to prevent variation in thickness of a gate insulating film immediately below the gate electrode during etching in manufacturing of bottom gate thin film transistor wherein a gate insulating film is formed after the semiconductor film is formed, it is possible to uniformly dope ions into the semiconductor film in the subsequent impurity ion doping stage.

An example of application of a top gate TFT with a gate electrode having a tapered side surface to a display device will now be described. Because the side surface of the gate electrode of the TFT as described has a tapered shape, it is possible to improve coverage of the interlayer insulating film formed above the gate electrode and to significantly improve flatness of the interlayer insulating film on the upper surface. Therefore, the TFT according to the embodiment is well suited for a control or driving thin film transistor, which, in many cases, is provided below an organic EL element. Because organic EL elements are formed by layering a plurality of thin films, when the unevenness of the surface below the organic EL element is significant, the thickness of the thin films may be impaired, which may in turn cause problems such as, for example, shorting of two electrodes sandwiching thin films made of organic layers or undesirable concentration of electric field which will result in “dark spots” where the EL emission is deficient and display is not possible. Thus, it is strongly demanded that the organic EL element be formed on a surface which is as flat as possible, and thus, the TFT according to the embodiment is well suited for this purpose. In the TFT according to the embodiment, polycrystalline silicon layer 13 can be used as the active layer, and, therefore, the TFT is capable of high-speed operation. Therefore, it is possible to include, on the same substrate as and in addition to pixel transistors, a driver transistor having, for example, a CMOS structure, which is a part of a peripheral driver circuit for controlling pixel transistors and having a structure similar to the pixel transistor.

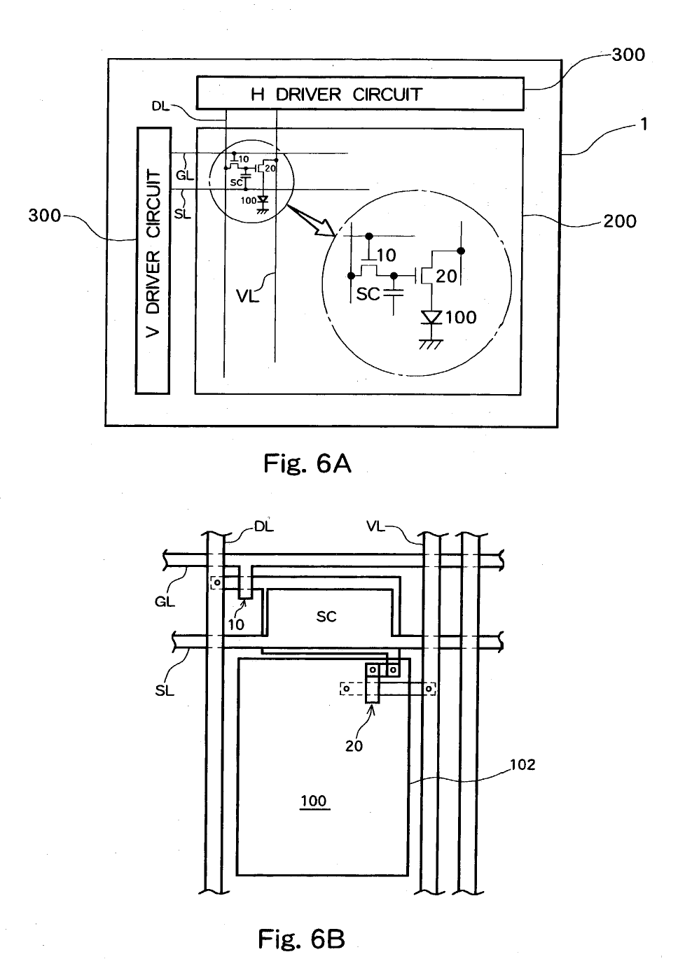

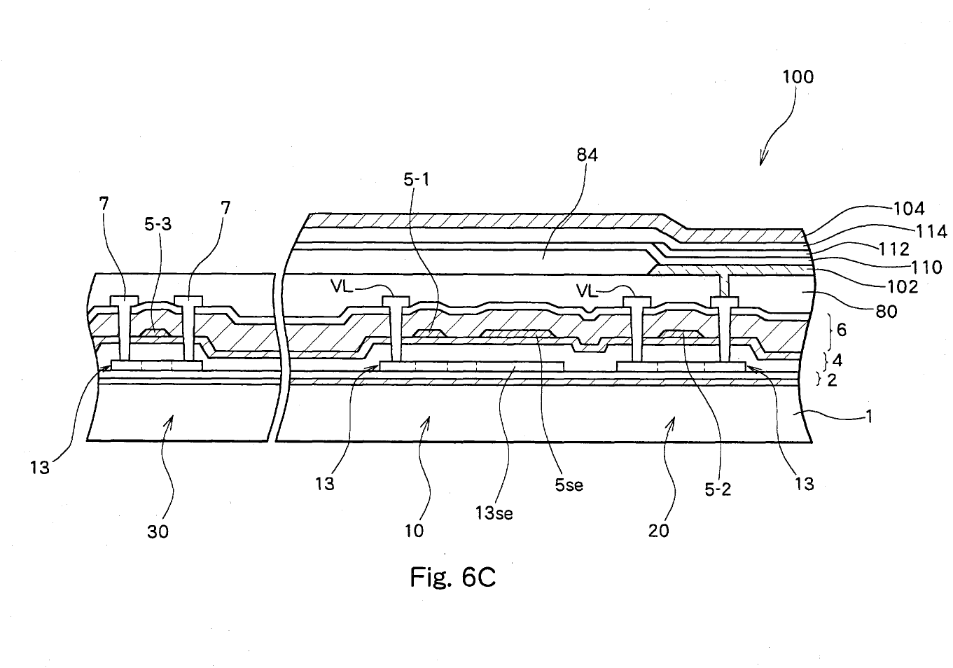

FIG. 6A is a diagram schematically showing a circuit structure of an active matrix organic EL display device having a peripheral driver circuit 300 and a pixel section 200 on the same substrate. FIG. 6B is a schematic diagram showing a planar structure within a pixel of this display device and FIG. 6C is a schematic diagram showing a cross sectional structure of an organic EL element 100 and TFTs 10, 20, and 30 in the pixel section 200 and in the peripheral deriver circuit 300. In this embodiment, among the circuits shown in FIG. 6A, a top gate TFT in which the gate electrode has a tapered shaped side surface is used as each of the transistors in the pixel section and in the peripheral driver circuit (TFTs 10, 20, and 30 in FIG. 6C).

In the illustrated configuration, a pixel comprises an organic EL (hereinafter abbreviated to “OEL”) element 100, a switching TFT (first TFT) 10, an OEL driving TFT (second TFT) 20, and a storage capacitor SC. The OEL element 100 comprises one or more organic layers (for example, a hole transport layer 110, an emissive layer 112, and/or an electron transport layer 114) formed between a first electrode (for example, an anode) 102 and a second electrode (for example, a cathode) 104. The first TFT 10 has its gate electrode 5-1 connected to (in the shown configuration, integrated with) a scan line (gate line) GL, is switched on by a scan signal, and reads a data signal supplied on a data line DL when switched on. The second TFT 20 supplies a current, corresponding to a voltage of a data signal applied to its gate electrode 5-2 through the first TFT 10, from a power source line VL to the OEL element 100 (in the illustrated configuration, the anode 102).

The storage capacitor SC is connected between a point between the first and second TFTs 10 and 20 and a storage capacitor line SL. The storage capacitor SC has a function to store charges corresponding to a data signal supplied through the first TFT 10 to apply a voltage corresponding to the stored charges, that is, a voltage corresponding to the data signal, to the gate electrode 5-2 of the second TFT 20 for a predetermined period. As shown in FIG. 6C, in the storage capacitor SC, a first electrode 5se and a second electrode 13se are formed in positions opposing each other with the gate insulating film 4 therebetween, and the storage capacitor SC is formed simultaneously with the first and second transistors 10 and 20. In particular, the first electrode 5se also functions as the capacitor line SL which is common to all pixels and is formed through patterning of an electrode material layer identical to the gate electrodes 5 (5-1, 5-2, and 5-3) having a tapered shaped side surfaces, which is performed simultaneously with the formation of the gate electrodes. The second electrode 13se is formed of the polycrystalline silicon layer, which is identical to the polycrystalline silicon layer (active layer) 13 of the first TFT 10.

In addition, a top gate TFT 30 within the peripheral driver circuit 300 placed in the periphery of the pixel section 200 is also formed to have a gate electrode 5-3 with a tapered side surface similar to the first and second TFTs 10 and 20 described above.

As described, according to the embodiment, all of the gate electrodes of the TFTs which are simultaneously formed have a tapered side surface. In addition, the electrodes which are patterned simultaneously with the gate electrode and from the same material are also formed to have tapered side surfaces. Because the organic layer of the OEL element is formed in the pixel portion, superior flatness of the lower layer and superior coverage of the insulating layer are demanded in the pixel portion, and, consequently, it is highly preferable to form gate electrodes 5-1 and 5-2 formed in an upper layer of the transistors with a tapered side surfaces, and, at the same time, to form an electrode (first electrode) 5se made of the same electrode material as the gate electrode with a tapered side surface. In the peripheral driver circuit 300, on the other hand, no organic layer is formed above the TFT, and, therefore, flatness above the TFT is not as strictly required in the region of the peripheral driver circuit 300. However, in an active matrix display device or the like, it is necessary to minimize the number of steps through simultaneous formation and patterning. In addition, in view of improving the coverage of the interlayer insulating film in the currently developing multi-layered structures, use of the tapered shape in the gate electrodes and the electrodes (for example, first electrode of storage capacitor) formed in the same step as these gate electrodes significantly contributes to improving the reliability of the device while only slightly increasing the manufacturing cost. In addition, because the side surfaces of the gate electrode and of the electrode are formed into a tapered shape through first and second etching stages as described, the conversion difference which is a difference between the resist mask width and the actual width of the electrode pattern is very small, which allows for inhibition of variation in the gate electrode width among a plurality of TFTs formed on the substrate. Therefore, because unevenness in the characteristics among a plurality of TFTs formed on the same substrate can be inhibited, uniformity of pixel display quality can be assured, and the characteristics of a display device can be improved. In addition, the structure also allows for prevention of variation in characteristics among a plurality of display devices.

What is claimed is:

1. A method for manufacturing a thin film transistor, comprising the steps of:
forming a semiconductor film above a substrate;
forming agate insulating film to cover the semiconductor film;
forming a gate electrode on the gate insulating film;
forming a source region and a drain region in the semiconductor film; and
forming an interlayer insulating film on the gate electrode, wherein
in the formation of the gate electrode, an electrode material layer is layered on the gate insulating film; a mask pattern is formed on the electrode material layer; a first etching process is applied in which the electrode material layer is etched using gas containing fluorine or gas containing a mixture of fluorine and oxygen, and with the mask pattern as a mask to a degree wherein a portion of the electrode material layer remains; and a second etching process is applied in which the electrode material layer is etched using a gas containing a mixture of chlorine and oxygen.

2. A method for manufacturing a thin film transistor according to claim 1, wherein
the source region and the drain region are formed by doping impurities into the semiconductor film through the gate insulating film.

3. A method for manufacturing a thin film transistor according to claim 1, wherein
the gate insulating film is obtained by layering a SiN film and a SiO₂ film or by forming one of the SiN film and SiO₂ film.

4. A method for manufacturing a thin film transistor according to claim 1, wherein
the source region and the drain region are formed by doping impurities into the semiconductor film through the gate insulating film; and
the gate insulating film is obtained by layering a SiN film and a SiO₂ film or by forming one of the SiN film and SiO₂ film.

5. A method for manufacturing a thin film transistor according to claim 1, wherein
the gas in the first etching process is produced by mixing fluorine-based gas and oxygen-based gas in an approximately equal volume ratio.

6. A method for manufacturing a thin film transistor, comprising the steps of:
forming a semiconductor film above a substrate;
forming a gate insulating film to cover the semiconductor film;
forming a gate electrode on the gate insulating film;
forming a source region and a drain region within the semiconductor film; and
forming an interlayer insulating film on the gate electrode, wherein
in the formation of the gate electrode, an electrode material layer is layered on the gate insulating film; a mask pattern is formed on the electrode material layer; and a first etching process and a second etching process are applied to the electrode material layer with the mask pattern made of a resist material as a mask, wherein
in the first etching process, an etching gas having a smaller etching selection ratio between the electrode material layer and the gate insulating film than an etching gas used in the second etching process and having a faster etching rate of the electrode material layer than the etching gas of the second etching process is used, and the electrode material layer is etched to a degree so that a predetermined thickness of the electrode material layer remains in regions not covered by the mask, and
in the second etching process, an etching gas having a larger etching selection ratio between the electrode material layer and the gate insulating film than the etching gas used in the first etching process and having a larger ashing rate of the mask pattern than the etching gas used in the first etching process is used to etch the electrode material layer remaining in the predetermined thickness, so that a gate electrode having a tapered shape wherein the side surface is inclined such that the width becomes narrower toward the upper surface is obtained.

7. A method for forming a thin film transistor having a semiconductor film and a gate electrode formed above a substrate, the method comprising:
a film forming step for layering an electrode material layer above the substrate;
a first etching step for etching, in a reaction chamber of an inductively coupled plasma apparatus having an inductively coupled plasma source and a biasing source, at least a portion of the electrode material layer using a mask pattern formed on the electrode material layer as a mask and by activating only the inductively coupled plasma source; and
a second etching step for etching, in a reaction chamber of the inductively coupled plasma apparatus, the electrode material layer which is etched in the first etching step by activating both the inductively coupled plasma source and the biasing source, wherein
a gate electrode having a side surface with a tapered shape is formed.

8. A method for manufacturing a thin film transistor according to claim 7, wherein
after a semiconductor film is formed above the substrate, the electrode material layer is formed above the semiconductor film.

9. A method for manufacturing a thin film transistor according to claim 8, wherein
after a gate insulating film is formed on the semiconductor film, the electrode material layer is formed on the gate insulating film.

10. A method for manufacturing a thin film transistor according to claim 7, wherein
after the side surface of the electrode material layer is formed into a tapered shape through the second etching step, the semiconductor film is formed.

11. A method for manufacturing a thin film transistor according to claim 7, wherein
in the first etching step, gas containing fluorine or a gas containing a mixture of fluorine and oxygen is used as the etching gas; and
in the second etching step, a gas containing a mixture of chlorine and oxygen is used as the etching gas.

12. A method for manufacturing a thin film transistor according to claim 11, wherein
after a semiconductor film is formed above the substrate, the electrode material layer is formed above the semiconductor film.

13. A method for manufacturing a thin film transistor according to claim 11, wherein
after a gate insulating film is formed on the semiconductor film, the electrode material layer is formed on the gate insulating film.

14. A method for manufacturing a thin film transistor according to claim 13, wherein
the gate insulating film is obtained by layering a SiN film and a SiO₂ film or by forming one of the SiN film and the SiO₂ film.

15. A method for manufacturing a thin film transistor according to claim 11, wherein
after the side surface of the electrode material layer is formed into a tapered shape through the second etching step, the semiconductor film is formed.

16. An active matrix display device in which a pixel section and a peripheral driver circuit provided in the periphery of the pixel section for driving the pixel section are formed on a substrate, wherein
each pixel in the pixel section comprises a display element and a pixel thin film transistor for controlling the display element;
the peripheral circuit comprises a plurality of driver thin film transistors;
the pixel thin film transistor and the driver thin film transistors each comprises:
a semiconductor film made of the same material among the thin film transistors;
a gate insulating film formed to cover the semiconductor film; and
a gate electrode formed on the gate insulating film, and
the gate electrode of each of the transistors has a tapered shape where in the side surface is inclined such that the width becomes narrower towards the upper layer and away from the gate insulating film.

17. An active matrix display device according to claim 16, wherein
the gate insulating film comprises one or both of SiN and SiO₂.

18. An active matrix display device according to claim 16, wherein
the pixel thin film transistor is covered by an interlayer insulating film, and
the display element is formed above the interlayer insulating film.

19. An active matrix display device according to claim 16, wherein
each of the pixels further comprises a storage capacitor;
the storage capacitor has a structure wherein a first electrode made of the same material as the gate electrode and a second electrode which is constructed by the semiconductor film are disposed with the gate insulating film therebetween; and
the first electrode formed on the gate insulating film has a tapered shape wherein the side surface is inclined such that the width becomes narrower towards the upper layer and away from the gate insulating film.

20. An active matrix display device according to claim 19, wherein
the taper angles between a formation plane and the side surface of the gate electrode of the pixel thin film transistor and of the driver thin film transistor are equal to the taper angle between the formation plane and the side surface of the first electrode of the storage capacitor.
